(19) United States
(12) Patent Application Publication
(10) Pub. No.: US 2025/0026629 A1
(43) Pub. Date: Jan. 23, 2025

(54) MEMS Array Structures for Gyroscopes with High Resonant Frequencies

(71) Applicant: NXP USA, Inc., Austin, TX (US)

(72) Inventors: Jun Tang, Gilbert, AZ (US); Aaron A. Geisberger, Austin, TX (US)

(73) Assignee: NXP USA, Inc., Austin, TX (US)

(21) Appl. No.: 18/222,926

(22) Filed: Jul. 17, 2023

(51) Int. Cl. B81B 3/00; B81C 1/00

(52) U.S. Cl. CPC B81B 3/0021; B81C 1/00174; B81B 2201/0242; B81B 2203/0118; B81B 2203/0181; B81B 2203/0307; B81B 2203/04; B81B 2207/07; B81C 2201/0104; B81C 2201/0132; B81C 2201/0142; B81C 2201/0147; B81C 2201/0176

(57) ABSTRACT

A MEMS inertial sensor device, method of operation, and fabrication process are described wherein a MEMS inertial sensor and drive actuation units are coupled together in operational engagement, where the MEMS inertial sensor includes a substrate and a proof mass array positioned in spaced apart relationship above a surface of the substrate and constructed with a plurality of proof mass sub-structures which are each separately connected to the substrate with orthogonally disposed pairs of spring suspension structures and which are each rigidly connected to one or more adjacent proof mass sub-structures with one or more connector bars so that the plurality of proof mass sub-structures move as a single proof mass array that can operate at resonant frequencies of at least 100 kHz when oscillating in first and second orthogonal directions.

### BACKGROUND OF THE INVENTION

### Field of the Invention

The present disclosure is directed in general to the field of integrated circuit (IC) Micro-Electro-Mechanical Systems (MEMS) devices. In one aspect, the present disclosure relates to MEMS inertial sensor devices and methods for operating same.

### Description of the Related Art

MEMS technology is increasingly used to integrate mechanical elements, sensors, actuators, and electronics on a common silicon substrate through microfabrication technology. For example, inertial sensors may be formed with MEMS devices on an integrated circuit wafer substrate to form various applications, such as gyroscopes and accelerometers for measuring linear acceleration and/or angular velocity in one or more sensing directions. A conventional IC MEMS device typically includes a movable element, such as a proof mass, diaphragm, mirror, and the like that is flexible or movable, and is movably attached to an integrated circuit device. The proof mass is resiliently suspended by one or more suspension springs such that it moves when the MEMS inertial sensor experiences movement, such as linear acceleration and/or angular velocity. Relative motion between this movable element and the rest of the device is driven by actuators and/or sensed by sensors in various ways, depending on device design. The motion of the proof mass may then be converted into an electrical signal having a parameter magnitude (e.g., voltage, current, frequency, etc.) that is proportional to the angular velocity. In some instances, a MEMS gyroscope may experience a mechanical shock or vibration which can disrupt the operation of the inertial sensor, such as by affecting the oscillating movement of the proof mass. Such mechanical disruptions typically occur at frequencies that can interfere with the operation of MEMS inertial sensors which operate with relatively low resonant frequencies (e.g., 15-50 kHz), thereby introducing sensing errors. Existing MEMS inertial sensors typically employ large proof mass elements having parasitic modes, such as plate bending modes, with frequencies that are affected by the mechanical shock/vibration frequencies. As a result, the existing design, operation, and manufacturability of integrated circuit MEMS inertial sensors are extremely difficult to implement at a practical level.

### BRIEF DESCRIPTION OF THE DRAWINGS

The present disclosure may be understood, and its numerous objects, features and advantages obtained, when the following detailed description of a preferred embodiment is considered in conjunction with the following drawings.

FIG. 1 is a simplified plan view of a proof sub-mass structure suspended over a substrate with one or more compliant anchor members to provide two orthogonal vibration modes in accordance with selected embodiments of the present disclosure.

FIG. 2 illustrates a simplified plan view of a single proof mass array formed with a plurality of proof sub-mass structures in accordance with selected embodiments of the present disclosure.

FIG. 3 is a simplified plan view of multiple arrays of rigidly connected proof sub-mass structures which are connected together by pivot structures to enable out-of-phase vibrations between the multiple arrays in accordance with selected embodiments of the present disclosure.

FIG. 4A illustrates a plan view of a Lissajous Frequency Modulation (LFM) z-axis MEMS gyroscope wherein a plurality of proof sub-mass structures are rigidly connected to form vertical array columns that are connected together by pivot structures to enable out-of-phase vibrations between the multiple vertical array columns in accordance with selected embodiments of the present disclosure.

FIG. 4B illustrates a plan view of the LFM z-axis MEMS gyroscope shown in FIG. 4A wherein alternating vertical array columns are oscillating out of phase with one another in the x-axis direction in accordance with selected embodiments of the present disclosure.

FIG. 4C illustrates a plan view of the LFM z-axis MEMS gyroscope shown in FIG. 4A wherein alternating vertical array columns are oscillating out of phase with one another in the y-axis direction in accordance with selected embodiments of the present disclosure.

FIG. 5A illustrates a plan view of a Lissajous Frequency Modulation (LFM) y-axis MEMS gyroscope wherein a plurality of proof sub-mass structures are rigidly connected to form horizontal array rows that are connected together by pivot structures to enable out-of-phase vibrations between the multiple vertical array columns in accordance with selected embodiments of the present disclosure.

FIG. 5B illustrates a plan view of the LFM y-axis MEMS gyroscope shown in FIG. 5A wherein alternating horizontal array rows are oscillating out of phase with one another in the x-axis direction in accordance with selected embodiments of the present disclosure.

FIG. 5C illustrates a perspective view of the LFM z-axis MEMS gyroscope shown in FIG. 5A wherein alternating horizontal array rows are oscillating out of phase with one another in the z-axis direction in accordance with selected embodiments of the present disclosure.

FIG. 6 depicts a simplified flow chart showing the processing steps for fabricating a MEMS sensor device in accordance with selected embodiments of the present disclosure.

### DETAILED DESCRIPTION

A high resonant frequency MEMS inertial sensor structure and method of fabrication are described wherein a proof mass array is constructed with a plurality of sub-mass structures which are each connected to anchors with spring suspensions and which are rigidly connected together form the proof mass array. With the arrangement of multiple, smaller, rigidly connected sub-mass structures to form a singular proof mass array, the resulting MEMS inertial sensor can operate at high resonant frequencies (e.g., 100 kHz) without having parasitic modes below that frequency, thereby improving robustness against environmental vibration shocks which have relatively lower frequencies. In selected embodiments, the MEMS inertial sensor may be formed as a Lissajous Frequency Modulation (LFM) gyroscope having an LFM proof mass array structure formed with one or more n×m arrays of proof mass sub-structures. Each proof mass sub-structure in the LFM proof mass is spaced apart from an underlying substrate surface and is suspended over the underlying substrate surface by one or more suspension spring or cantilever beam elements which connect the proof mass sub-structure to one or more substrate anchor structures. In each n×m array of proof mass sub-structure, adjacent proof mass sub-structures are rigidly connected together by proof mass connector elements to form the LFM proof mass array structure. The rigid connection ensures synchronized frequency and mode shape for all sub-structures. In selected embodiments, adjacent rows or columns of n×m array of proof mass sub-structures in an LFM proof mass are coupled to one another by one or more pivot structures to enable differential out of phase oscillating movement by the LFM proof mass array structure.

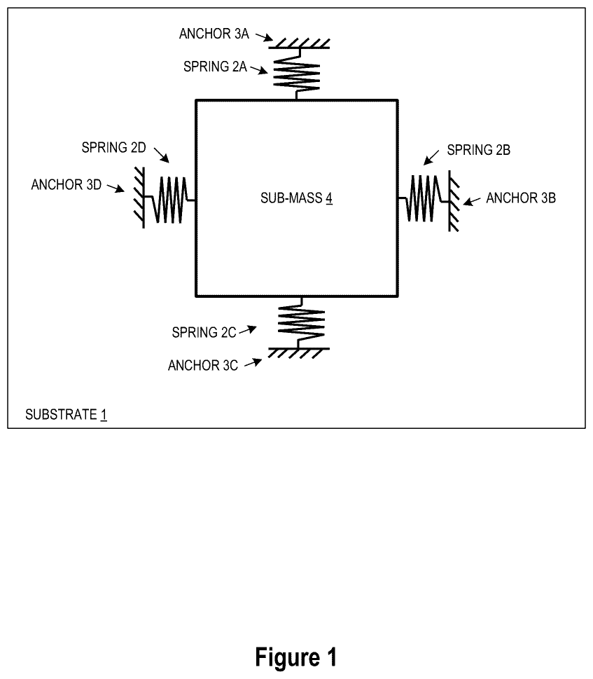

FIG. 1 is a simplified plan view of a 2-DOF (degrees of freedom) proof sub-mass structure 4 suspended over a substrate 1 with one or more compliant anchor members 2-3 which are fixed to the substrate 1 to provide two orthogonal vibration modes in accordance with selected embodiments of the present disclosure. Though shown as simplified square shapes, the proof sub-mass structure 4 may be formed with one or more patterned semiconductor layer having any suitable geometric shape. For example, the proof sub-mass structure 4 may include a number of movable fingers or electrodes which are positioned to interact with fixed electrodes attached to the substrate 1 in order to impart oscillating motion to the proof sub-mass structure 4. To suspend each proof sub-mass structure 4 above the underlying substrate 1, one or more compliant anchor members 2-3 are interconnected between the proof sub-mass structure 4 the substrate 1. In selected embodiments, the compliant anchor members may be implemented by connecting spring elements 2A-D between the peripheral side of the proof sub-mass structure 4 and anchor elements 3A-D fixed to the substrate. In this way, the compliant anchor members 2-3 enable oscillating movement of the proof sub-mass structure 4 with two degrees of freedom. In particular, the spring/anchor elements 2A/3A, 2C/3C attached to the top and bottom sides enable movement of the proof sub-mass structure 4 in the y-axis direction. In addition, the spring/anchor elements 2B/3B, 2D/3D attached to the left and right sides enable movement of the proof sub-mass structure 4 in the x-axis direction. In other embodiments, there may be additional or fewer compliant anchor members 2A-D, 3A-D than those shown, and/or compliant anchor members 2A-D, 3A-D may be attached to other locations on the proof sub-mass structure 4 than shown. Though represented by spring symbols for simplicity of illustration, persons skilled in the art will recognize that compliant anchor members 2A-D, 3A-D can take on various structural forms in actual practice, including but not limited to cantilevered suspension beam structures, folded beam structures, beam spring structures, and the like. Constructed as a dual axis sub-mass structure 4, the compliant anchor members 2A-D, 3A-D enable movement of the proof sub-mass structure 4 to resonate at desired mode shapes and frequencies, including high target frequencies, such as above 100 kHz. In addition, the parasitic modes for the proof sub-mass structure 4 should have frequencies much higher than the operational modes since the proof sub-mass structure 4 is relatively small.

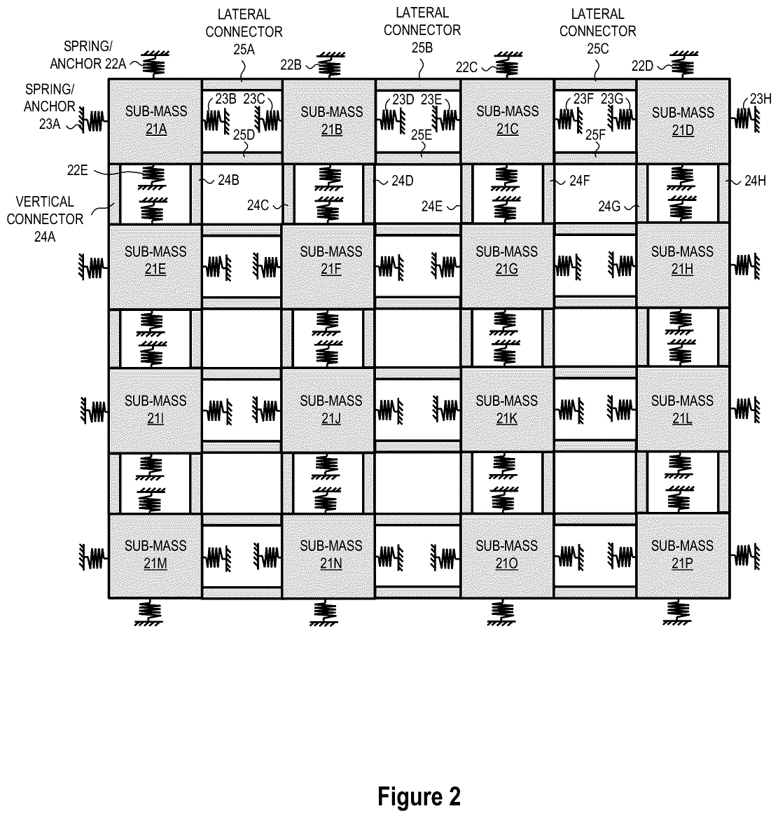

To provide additional details for an improved understanding of selected embodiments of the present disclosure, reference is now made to FIG. 2 which depicts a simplified plan view of a single proof mass array 2 formed with a plurality of proof sub-mass structures 21A-P which are connected together with rigid vertical connectors 24A-H, etc. and rigid lateral connectors 25A-F, etc. Though shown as a 4×4 array of 16 square-shaped proof sub-mass structures 21A-P, the single proof mass array 2 may be formed with any suitable n×m array of proof sub-mass structures 21 having any suitable geometric shape by using any suitable MEMS fabrication processing steps, such as by selectively patterning, and releasing one or more semiconductor layers to be suspended above and compliantly anchored to the underlying substrate.

As formed, each contributing proof sub-mass structure (e.g., 21A) includes one or more compliant anchor members (e.g., 22A/E, 23A/B) that connect the proof sub-mass structure to the substrate to enable oscillating movement having one or more degrees of freedom (e.g., in the x-axis and y-axis directions). Though represented by spring symbols for simplicity of illustration, persons skilled in the art will recognize that compliant anchor members 22A-E, etc. and 23A-H, etc. can take on various structural forms in actual practice, including but not limited to cantilevered suspension beam structures, folded beam structures, beam spring structures, and the like. As will be appreciated, the compliant anchor members 22A-E, 23A-H may be formed using any suitable MEMS fabrication processing steps to define spring elements 22A-E, 23A-H which connect the peripheral side(s) of each proof sub-mass structure 21A-P to corresponding anchor element(s) fixed to the substrate.

To enable the proof sub-mass structures 21A-P to move as a single proof mass, horizontally adjacent proof sub-mass structures (e.g., 21A, 21B) are rigidly connected together with rigid lateral connectors (e.g., 25A, 25D), horizontally adjacent proof sub-mass structures (e.g., 21B, 21C) are rigidly connected together with rigid lateral connectors (e.g., 25B, 25E), and so on. In addition, vertically adjacent proof sub-mass structures (e.g., 21A, 21E) are rigidly connected together with rigid vertical connectors (e.g., 24A, 24B), vertically adjacent proof sub-mass structures (e.g., 21B, 21F) are rigidly connected together with rigid vertical connectors (e.g., 24C, 24D), and so on, so that every proof sub-mass structure 21A-P is rigidly connected to form the single proof mass array 2. Though shown as having a simplified linear shape, the rigid connector structures 24A-H, 25A-F may be formed with any geometric shape using any suitable MEMS fabrication processing steps, such as by selectively patterning, and releasing one or more semiconductor layers to be suspended above the underlying substrate and to rigidly connect adjacent proof sub-mass structures. With the single proof mass array 2 having a fixed and rigidly connected structure, the movable and fixed electrodes (not shown) in the single proof mass array 2 may be used to impart synchronized mode shapes and resonant frequencies to all connected proof sub-mass structures 21A-P, thereby providing a controlled oscillating motion to the single proof mass structure 2. In this configuration, the connected array of proof sub-mass structures 21A-P can operate at desired mode shapes with synchronized high resonant frequencies (e.g., >100 kHz) that are above most shock frequencies.

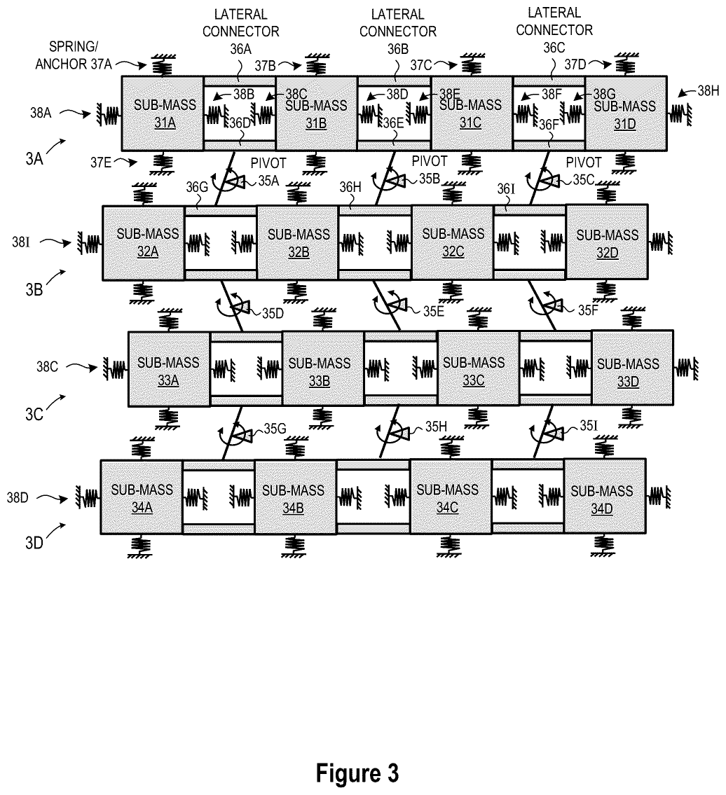

To provide additional details for an improved understanding of selected embodiments of the present disclosure, reference is now made to FIG. 3 which depicts a simplified plan view of a single proof mass array 3 formed with a plurality of proof mass sub-arrays 3 A-D, each formed with rigidly connected proof sub-mass structures 31A-D, 32A-D, 33A-D, 34A-D which are connected together by anti-phase coupling or pivot structures 35A-I to allow anti-phase oscillating motion between adjacent proof mass arrays. Though shown as 16 square-shaped proof sub-mass structures 31A-D, 32A-D, 33A-D, 34A-D arranged and connected in four 1×4 proof mass sub-arrays 3A-D, the single proof mass array 3 may be formed with any desired number of pivot-connected n×m proof mass sub-arrays of rigidly connected proof sub-mass structures 34A-D having any suitable geometric shape by using any suitable MEMS fabrication processing steps, such as by selectively patterning, and releasing one or more semiconductor layers to be suspended above and compliantly anchored to the underlying substrate.

As formed, each contributing proof sub-mass structure (e.g., 31A) includes one or more compliant anchor members (e.g., 37A/E, 38A/B) that connect the proof sub-mass structure to the substrate to enable oscillating movement having one or more degrees of freedom (e.g., in the x-axis and y-axis directions). Though represented by spring symbols for simplicity of illustration, persons skilled in the art will recognize that compliant anchor members 37A-E, etc. and 38A-I, etc. can take on various structural forms in actual practice, including but not limited to cantilevered suspension beam structures, folded beam structures, beam spring structures, and the like. As will be appreciated, the compliant anchor members 37, 38 may be formed using any suitable MEMS fabrication processing steps to define spring elements 37, 38 which connect the peripheral side(s) of each proof sub-mass structure 34A-D to corresponding anchor element(s) fixed to the substrate.

To enable the proof sub-mass structures (e.g., 31A-D) in each proof mass sub-array (e.g., 3A) to move as a single proof mass, horizontally adjacent proof sub-mass structures (e.g., 31A, 31B) are rigidly connected together with rigid lateral connectors (e.g., 36A, 36D). Though shown as having a simplified linear shape, the rigid connector structures 36 may be formed with any geometric shape using any suitable MEMS fabrication processing steps, such as by selectively patterning, and releasing one or more semiconductor layers to be suspended above the underlying substrate and to rigidly connect adjacent proof sub-mass structures.

In addition, the proof sub-mass structures (e.g., 31A-D) in adjacent arrays (e.g., 3A, 3B) are connected or coupled over one or more coupling structures 35A-I which are fixedly coupled or connected to the substrate and configured with flexible or compliant members to allow anti-phase motion between the adjacent proof mass sub-arrays 3A-3D. In selected embodiments, each coupling structure (e.g., 35A) may be formed and positioned as a pivot structure which is positioned and attached to rigid lateral connectors (e.g., 36D, 36G) from adjacent proof mass sub-arrays (e.g., 3A, 3B). In other embodiments, the coupling structures 35A-I may be formed and positioned as pivot structures which are attached to proof sub-mass structures (e.g., 31A, 32A) from adjacent proof mass sub-arrays (e.g., 3A, 3B). In this way, the coupling/pivot structures 35A-I are configured to prevent adjacent proof mass sub-arrays (e.g., 3A, 3B) from moving in-phase, as denoted by the rotational oppositely facing arrows interconnected by a pivot linkage (e.g., 35A). Thus, coupling/pivot structures 35A-I are configured to ideally reject in-phase (e.g., common mode) motion of adjacent proof mass sub-arrays 3A-D.

With the single proof mass array 3 having multiple proof mass sub-arrays 3A-D that ae each formed with fixed and rigidly connected proof sub-mass structures 31A-D, 32A-D, 33A-D, 34A-D and connected via coupling/pivot structures 35A-I, the movable and fixed electrodes (not shown) in the single proof mass array 3 may be used to impart out of phase lateral movement of the proof mass sub-arrays 3A-D. In this configuration, the connected array of proof sub-mass structures 31A-D, 32A-D, 33A-D, 34A-D can achieve differential mode shapes with synchronized high resonant frequencies (e.g., >100 kHz) that are above most shock frequencies.

In accordance with the present disclosure, an advantageous benefit of the unique proof mass array structure design described herein is the ability to achieve high resonance frequency operation for gyroscopes, such as the ones shown in FIGS. 1-3. In addition, by using the disclosed array(s) of proof sub-mass structures having their own spring suspensions and being rigidly linked, the gyroscope designs can achieve desired mode shapes with synchronized very high resonant frequencies, thereby providing improved robustness over environmental vibrations with relatively low frequencies. In addition, by using the disclosed unique proof mass array structure design, adjacent proof mass sub-arrays are coupled together with pivot structures to achieve synchronized out-of-phase oscillation modes while still remaining independent of each other in each proof mass array structure. The lateral connectors (e.g., 25A-F) coupling between the proof sub-mass structures 21A-P promote a first x-axis oscillation mode and resist the undesired co-phasal oscillation modes. Similarly, the vertical connectors (e.g., 24A-H) coupling between the proof sub-mass structures 21A-P promote a second y-axis oscillation mode and resist the undesired co-phasal oscillation modes. By forming the proof mass array structure with array of smaller proof sub-mass structures, first and second oscillation modes may be obtained which resonate above 100 kHz without parasitic modes below that frequency, thereby providing robust oscillation modes which are not easily disturbed by external vibrations. In selected embodiments, the first and second oscillation modes can be made independent of each other by connecting adjacent proof mass sub-arrays with one or more x-axis or y-axis anti-phase structures which are constructed an in-plane seesaw structures with a central elongated bar which is suspended from at least one central anchor point with at least one central seesaw suspender which allows the central elongated bar to rotate in the device plane about an axis which is perpendicular to the device plane. This is because each central elongated bar which synchronizes the movement of adjacent proof mass sub-arrays in the lateral/transversal direction can easily be joined to coupling elements which are rigid in the same (lateral/transversal) direction but flexible in the orthogonal (transversal/lateral) direction.

In selected embodiments, the gyroscope employing the proof mass array structure design described herein may be operated as an amplitude-modulated gyroscope where the drive transducers actuate the rigidly connected proof sub-mass structures 21A-P to move as a single proof mass array 2 in a primary oscillation mode (e.g., oscillating in the x-axis direction) having a predetermined amplitude which is kept as constant as possible. When the gyroscope undergoes angular rotation, the Coriolis force sets the proof sub-mass structures 21A-P to oscillate also in a secondary oscillation mode (e.g., oscillating in the y-axis direction) where the amplitude of the secondary oscillation is proportional to the angular rotation rate and to the amplitude of the primary oscillation. This amplitude can be measured with sense transducers which are configured to generate a sense signal which is proportional to the transversal displacement of the rigidly connected proof sub-mass structures 21A-P. By operating the single proof mass array 2 with very high resonant frequencies (e.g., above 100 kHz, the gyroscope has immunity to disturbances generated by external shock vibrations that have much lower frequencies.

In other embodiments, the gyroscope employing the proof mass array structure design described herein may be operated as a frequency-modulated gyroscope where the drive transducers actuate the rigidly connected proof sub-mass structures 21A-P simultaneously into both the first and the second oscillation modes. The oscillation amplitude may be substantially the same in the first and the second oscillation mode, so that the drive electrodes actuate each proof sub-mass structure 21A-P into substantially circular movement. With the direction and oscillation and oscillation frequency of the circular motion being the same for each proof sub-mass structure 21, when the gyroscope undergoes angular rotation, the Coriolis force either reduces or increases the oscillation frequency of the circular motion, and the frequency change can be measured with sense electrodes which are configured to generate a sense signal which is proportional to the transversal displacement of the rigidly connected proof sub-mass structures 21A-P. By operating the single proof mass array 2 with very high resonant frequencies, the gyroscope has immunity to disturbances generated by external shock vibrations that have much lower frequencies.

In yet other embodiments, the gyroscope employing the proof mass array structure design described herein may be operated as a Lissajous frequency-modulated (LFM) gyroscope where the drive electrodes actuate the rigidly connected proof sub-mass structures 21A-P simultaneously into both the first and the second oscillation modes which have slightly different resonance frequencies fᵣₑₛ₋ₓ, f_{res-y} that differ by a predetermined amount f_{Δ}=fᵣₑₛ₋ₓ−f_{res-y} which, by design, causes the rigidly connected proof sub-mass structures 21A-P to precess in the xy-plane following the so-called Lissajous trajectory. In presence of an angular rate orthogonal to the plane of motion, the Coriolis force couples the two modes, resulting in oscillating frequency change as a function of the angular rate as follows: Σϕ_{xy}=ω₀ₓ+ω_{0y}−2α_{z}Ω_{z} sin Δϕ_{xy}; where the change of the frequency can be measured with sense electrodes which are configured to generate a sense signal which is proportional to the transversal displacement of the rigidly connected proof sub-mass structures 21A-P. By operating the single proof mass array 2 with very high resonant frequencies, the gyroscope has immunity to disturbances generated by external shock vibrations that have much lower frequencies.

In yet other embodiments, the gyroscope employing the proof mass array structure design described herein may be operated as a Lissajous frequency-modulated (LFM) gyroscope where the drive electrodes actuate a plurality of proof mass sub-arrays 3A-D so that adjacent proof mass sub-arrays 3A, 3C are circulating out of phase with proof mass sub-arrays 3B, 3D. Such a differential configuration allows the elimination of frequency shifts caused by other common factors, such as package warpage, temperature change, and so on. In presence of an angular rate orthogonal to the plane of motion, the Coriolis force couples the two modes, results in oscillating frequency change as a function of the angular rate as follows: Σϕ_{xy}=ω₀ₓ+ω_{0y}−2α_{z}Ω_{z} sin Δϕ_{xy}; where the change of the frequency can be measured with sense electrodes which are configured to generate a sense signal which is proportional to the transversal displacement of the rigidly connected proof sub-mass structures 31A-P, 32A-P, 33A-P, 34A-P. By operating the single proof mass array 3 with very high resonant frequencies, the gyroscope has immunity to disturbances generated by external shock vibrations that have much lower frequencies.

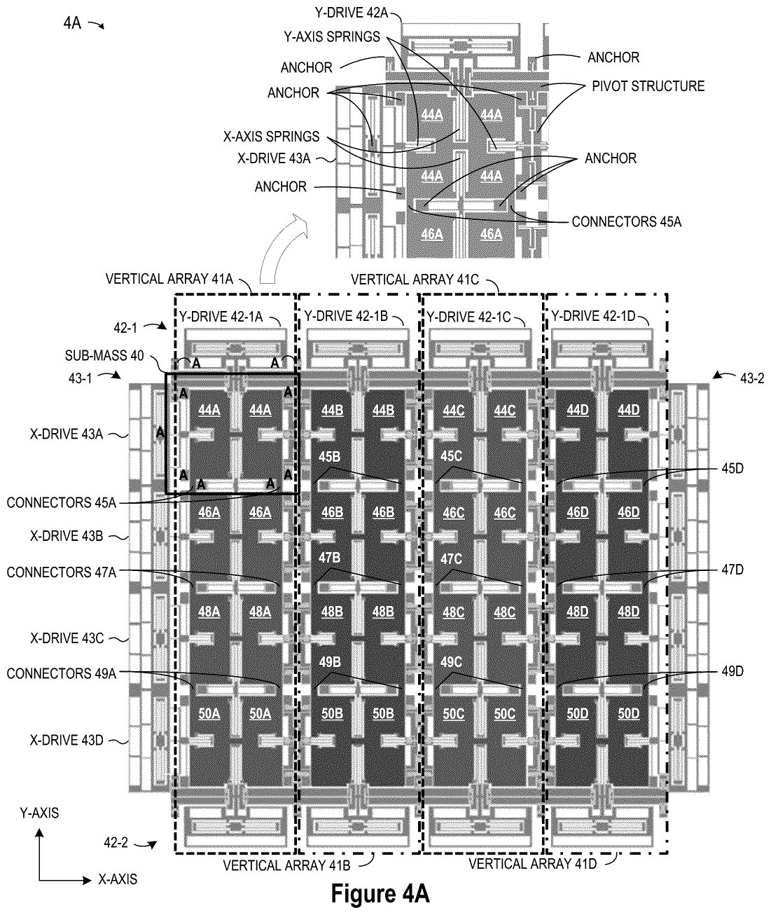

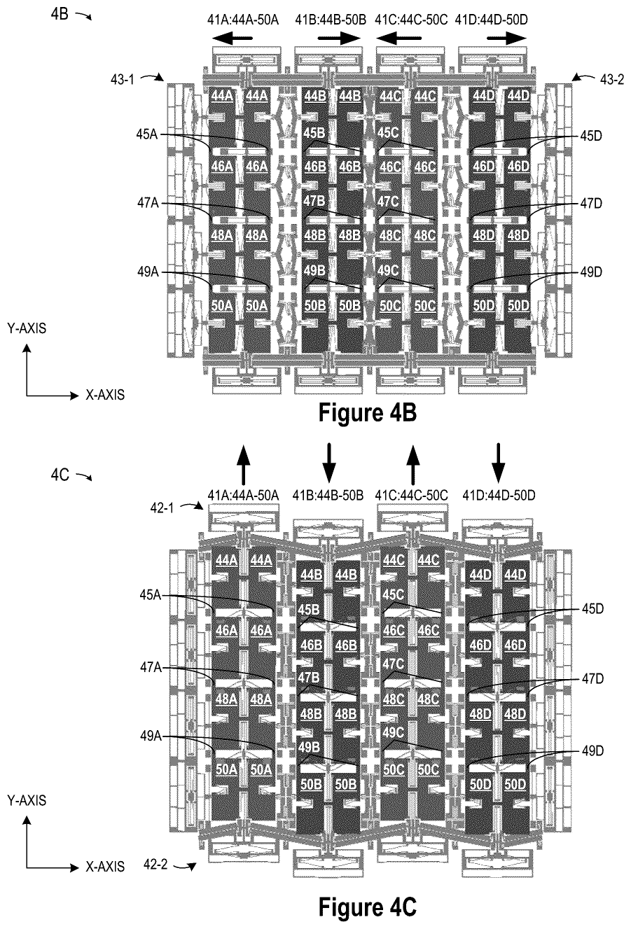

To provide additional details for an improved understanding of selected embodiments of the present disclosure, reference is now made to FIG. 4A which depicts a plan view of a Lissajous Frequency Modulation (LFM) z-axis MEMS gyroscope 4A. As formed, the gyroscope 4A includes a plurality of proof sub-mass structures 44A-D, 46A-D, 48A-D, 50A-D, each of which is substantially symmetrical in shape (e.g., a “square” shape) with integrated x-axis and y-axis suspension springs anchored to the substrate. In addition, proof sub-mass structures (e.g., 44A, 46A, 48A, 50A) in each vertical column are rigidly connected together by vertical connectors (e.g., 45A, 47A, 49A) to form a vertical or column array (e.g., 41A). In addition, the gyroscope 4A includes pivot structures for connecting adjacent vertical or column arrays (e.g., 41A, 41B), thereby enabling out-of-phase oscillations between the multiple vertical arrays 41A-D. While the gyroscope 4A is depicted as being formed with a 4×4 array of 16 proof sub-mass structures 44A-D, 46A-D, 48A-D, 50A-D, it will be appreciated that any suitable n×m array of spring-anchored proof sub-mass structures having any suitable geometric shape may be formed using any suitable MEMS fabrication processing steps, such as by selectively patterning, and releasing one or more semiconductor layers to be suspended above and compliantly anchored to the underlying substrate.

Disposed centrally or on opposing left and right sides of each of the proof sub-mass structures 44A-D, 46A-D, 48A-D, 50A-D, x-axis suspension springs extend to couple the proof sub-mass structure to one or more corresponding anchor points A. In similar fashion, y-axis suspension springs are disposed centrally or on opposing top and bottom sides of each of the proof sub-mass structures 44A-D, 46A-D, 48A-D, 50A-D to couple the proof sub-mass structure to one or more corresponding anchor points A. As will be appreciated, the corresponding anchor points can be located at any desired position relative to the proof sub-mass structure, and do not have to be aligned symmetrically with the proof sub-mass structure. It will also be appreciated that there may be one or more parallel x-axis/y-axis suspension springs on each side of the proof sub-mass structure. Given the relatively small size and the independent x-axis and y-axis suspension spring systems for each of the proof sub-mass structures 44A-D, 46A-D, 48A-D, 50A-D, each sub-mass spring system can operate with resonant frequencies at both in-plane x-axis and y-axis directions above 100 kHz.

In addition, the gyroscope 4A includes vertical connectors 45A-D, 47A-D, 49A-D for rigidly linking vertical columns of proof sub-mass structures 44A-D, 46A-D, 48A-D, 50A-D to form four larger proof mass sub-arrays 41A-D. As a result, each vertical or column array (e.g., 41A-D) can have independent oscillating movement in response to the drive transducer actuation from the y-drive actuators 42-1, 42-2 and x-drive actuators 43-1, 43-2. Thus, the first vertical column array 41A of proof sub-mass structures 44A, 46A, 48A, 50A can oscillate in the y-axis direction in response to the y-drive actuators 42-1A, 42-2A, the second vertical column array 41B of proof sub-mass structures 44B, 46B, 48B, 50B can oscillate in the y-axis direction in response to the y-drive actuator 42-1B, 42-2B, and so on. And by using coupling or pivot structures to connect adjacent proof mass sub-arrays 41A-D, the gyroscope can generate x-axis and y-axis oscillation of adjacent vertical column arrays 51A-D to achieve differential mode shapes at the higher resonant frequencies to mitigation or eliminate interference from lower frequency parasitic modes or environmental impacts.

To illustrate a first example of how oscillating in-plane x-axis motion may be imparted to the gyroscope 4A in accordance with selected embodiments of the present disclosure, reference is now made to FIG. 4B which illustrates a plan view of the LFM z-axis MEMS gyroscope shown in FIG. 4A. As illustrated, the first and third proof mass sub-arrays 41A, 41C are formed, respectively, with a proof sub-mass structures and connectors 44A-50A and proof sub-mass structures and connectors 44C-50C. Similarly, the second and fourth proof mass sub-arrays 41B, 41D are respectively formed with a proof sub-mass structures and connectors 44B-50B and proof sub-mass structures and connectors 44D-50D. In response to the drive transducer actuation from the x-drive actuators (e.g., 43-1, 43-2), alternating vertical array columns 41A-D are oscillating out of phase with one another in the x-axis direction. In particular, the first and third proof mass sub-arrays 41A, 41C are moving to the left and out of phase compared to the second and fourth proof mass sub-arrays 41B, 41D which are moving to the right, thereby providing a first lateral oscillation mode shape at a very high resonant frequency.

To illustrate a second example of how oscillating in-plane y-axis motion may be imparted to the gyroscope 4A in accordance with selected embodiments of the present disclosure, reference is now made to FIG. 4C which illustrates a plan view of the LFM z-axis MEMS gyroscope shown in FIG. 4A. As illustrated, the first and third proof mass sub-arrays 41A, 41C are formed, respectively, with a proof sub-mass structures and connectors 44A-50A and proof sub-mass structures and connectors 44C-50C. Similarly, the second and fourth proof mass sub-arrays 41B, 41D are respectively formed with a proof sub-mass structures and connectors 44B-50B and proof sub-mass structures and connectors 44D-50D. In response to the drive transducer actuation from the y-drive actuators (e.g., 42-1, 42-2), alternating vertical array columns 41A, 41C are oscillating out of phase with respect to vertical array columns 41B, 41D in the y-axis direction. In particular, the first and third proof mass sub-arrays 41A, 41C are moving up and out of phase compared to the second and fourth proof mass sub-arrays 41B, 41D which are moving to down, thereby providing a second vertical oscillation mode shape at a very high resonant frequency.

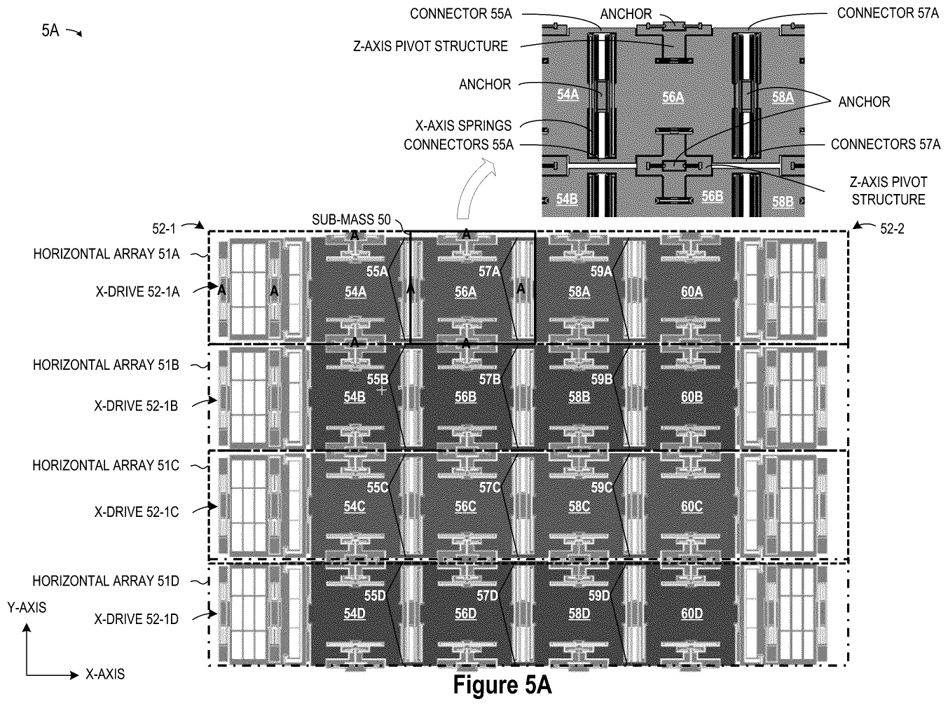

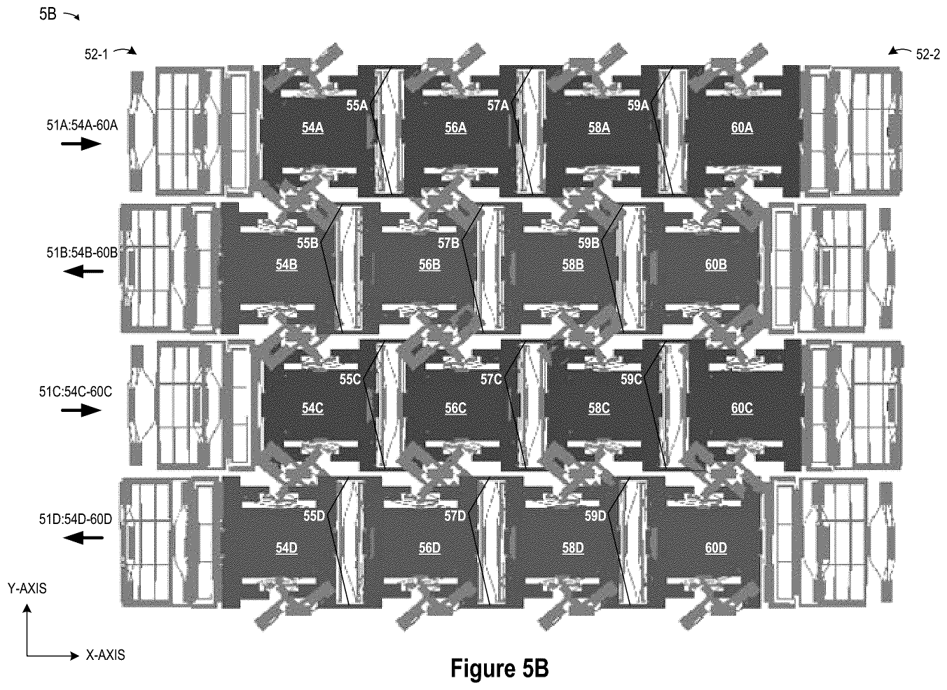

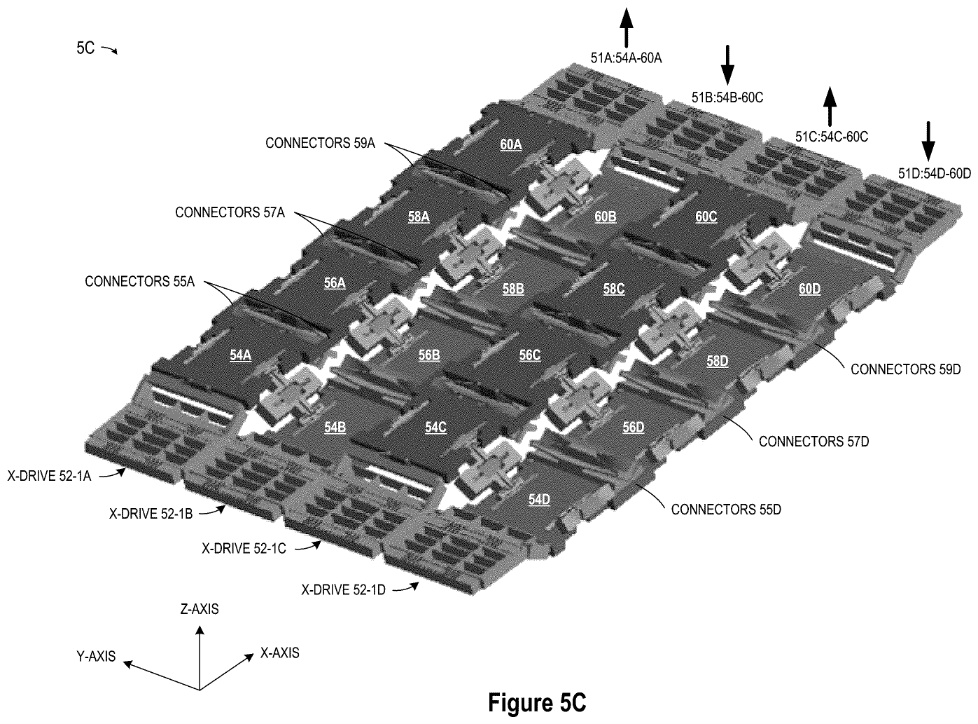

To provide additional details for an improved understanding of selected embodiments of the present disclosure, reference is now made to FIG. 5A which depicts a plan view of an LFM y-axis MEMS gyroscope 5A. As formed, the gyroscope 5A includes a plurality of proof sub-mass structures 54A-D, 56A-D, 58A-D, 60A-D, each of which is substantially symmetrical in shape (e.g., a “square” shape) with integrated x-axis suspension springs and z-axis pivot structures anchored to the substrate. In addition, proof sub-mass structures 54A, 56A, 58A, 60A are rigidly connected together by lateral connectors (e.g., 55A, 57A, 59A) to form a first horizontal row or array 51A. In addition, proof sub-mass structures 54B, 56B, 58B, 60B are rigidly connected together by lateral connectors 55B, 57B, 59B to form a second horizontal row or array 51B, and so on to form the additional horizontal arrays 51C-D. In addition, the gyroscope 5A includes z-axis pivot structures for connecting adjacent horizontal arrays (e.g., 51A, 51B), thereby enabling out-of-phase oscillation between the multiple horizontal arrays 51A-D. While the gyroscope 5A is depicted as being formed with a 4×4 array of 16 proof sub-mass structures 54A-D, 56A-D, 58A-D, 60A-D, it will be appreciated that any suitable n×m array of spring-anchored proof sub-mass structures having any suitable geometric shape may be formed using any suitable integrated circuit processing steps, such as by selectively patterning, and releasing one or more semiconductor layers to be suspended above and compliantly anchored to the underlying substrate.

Disposed centrally or on opposing left and right sides of each of the proof sub-mass structures 54A-D, 56A-D, 58A-D, 60A-D, x-axis suspension springs extend to couple the proof sub-mass structure to one or more corresponding anchor points A. In similar fashion, z-axis pivot structures are disposed on opposing top and bottom sides of each of the proof sub-mass structures 54A-D, 56A-D, 58A-D, 60A-D to couple the proof sub-mass structure to one or more corresponding anchor points A. As will be appreciated, the corresponding anchor points can be located at any desired position relative to the proof sub-mass structure, and do not have to be aligned symmetrically with the proof sub-mass structure. It will also be appreciated that there may be one or more parallel x-axis suspension springs/z-axis pivot structures on each side of the proof sub-mass structure. Given the relatively small size and the independent suspension/pivot structure systems for each of the proof sub-mass structures 54A-D, 56A-D, 58A-D, 60A-D, each sub-mass spring system can operate with resonant frequencies at both in-plane x-axis and y-axis directions above 100 kHz.

In addition, the gyroscope 5A includes horizontal or lateral connectors 55A-D, 57A-D, 59A-D for rigidly linking horizontal rows of proof sub-mass structures 54A/56A/58A/60A, 54B/56B/58B/60A, 54C/56C/58C/60C, 54D/56D/58D/60D to form four larger proof mass sub-arrays 51A-D. As a result, each horizontal array (e.g., 51A-D) can have independent oscillating movement in response to the drive transducer actuation from the x-drive actuators 52-1, 52-2 and z-drive actuators (not shown). Thus, the first horizontal row array 51A of proof sub-mass structures 54A, 56A, 58A, 60A can oscillate in the x-axis direction in response to the x-drive actuators 52-1A, 52-2A, the second horizontal row array 51B of proof sub-mass structures 54B, 56B, 58B, 60B can oscillate in the x-axis direction in response to the x-drive actuator 52-1B, 52-2B, and so on. And by using coupling or pivot structures to connect adjacent proof mass sub-arrays 51A-D, the gyroscope can generate differential z-axis and x-axis oscillation of adjacent horizontal row arrays 51A-D to achieve differential mode shapes at the higher resonant frequencies to mitigation or eliminate interference from lower frequency parasitic modes or environmental impacts.

To illustrate a first example of how oscillating in-plane x-axis motion may be imparted to the gyroscope 5A in accordance with selected embodiments of the present disclosure, reference is now made to FIG. 5B which illustrates a plan view of the LFM y-axis MEMS gyroscope shown in FIG. 5A. As illustrated, the first and third proof mass sub-arrays 51A, 51C are formed, respectively, with a proof sub-mass structures and connectors 54A-60A and proof sub-mass structures and connectors 54C-60C. Similarly, the second and fourth proof mass sub-arrays 51B, 51D are respectively formed with a proof sub-mass structures and connectors 54B-60B and proof sub-mass structures and connectors 54D-60D. In response to the drive transducer actuation from the x-drive actuators (e.g., 52-1, 52-2), alternating vertical array columns 51A-D are oscillating out of phase with one another in the x-axis direction. In particular, the first and third horizontal proof mass sub-arrays 51A, 51C are moving in the x-axis direction to the right and out of phase compared to the second and fourth horizontal proof mass sub-arrays 51B, 51D which are moving in the x-axis direction to the left, thereby providing a first lateral oscillation mode shape at a very high resonant frequency.

To illustrate a second example of how oscillating out-of-plane z-axis motion may be imparted to the gyroscope 5A in accordance with selected embodiments of the present disclosure, reference is now made to FIG. 5C which illustrates a perspective view of the LFM y-axis MEMS gyroscope shown in FIG. 5A. As illustrated, the first and third proof mass sub-arrays 51A, 51C are formed, respectively, with a proof sub-mass structures and connectors 54A-60A and proof sub-mass structures and connectors 54C-60C. Similarly, the second and fourth proof mass sub-arrays 51B, 51D are respectively formed with a proof sub-mass structures and connectors 54B-60B and proof sub-mass structures and connectors 54D-60D. In response to the drive transducer actuation from the z-drive actuators (not show), alternating horizonal array rows 51A, 51C are oscillating out of phase with respect to horizonal array rows 51B, 51D in the z-axis direction. In particular, the first and third proof mass sub-arrays 51A, 541C are moving up in the z-axis direction and out of phase compared to the second and fourth proof mass sub-arrays 51B, 51D which are moving to down in the z-axis direction, thereby providing a second vertical oscillation mode shape at a very high resonant frequency.

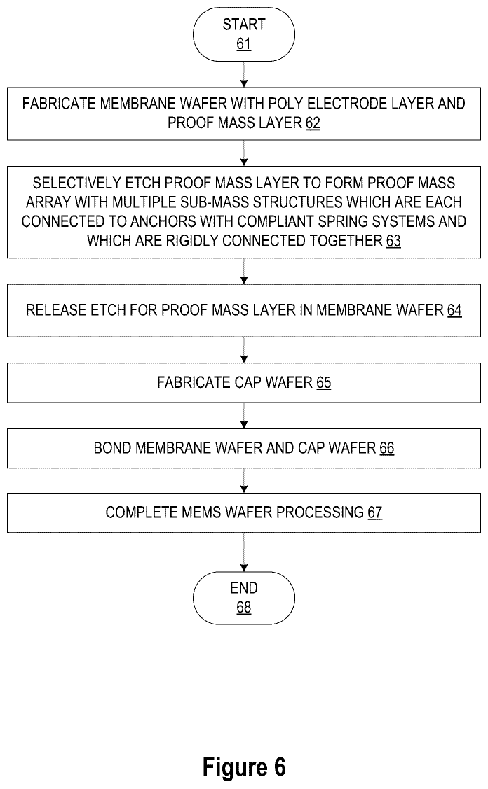

To provide additional details for an improved understanding of selected embodiments of the present disclosure, reference is now made to FIG. 6 which depicts a simplified flow chart 6 showing the processing steps 61-68 for fabricating a MEMS sensor device. As will be appreciated, the specific sequence of steps may be modified or changed. In addition, certain steps, such as handle wafer or cap wafer fabrication steps, may be omitted or performed separately.

After the process begins at step 61, a membrane wafer is fabricated which has one or more semiconductor proof mass layers formed over an electrode layer (step 62). In selected embodiments, the membrane wafer may be fabricated on a first crystal silicon wafer substrate using a sequence of processing steps to deposit, pattern and etch insulator layers and one or more conductive electrode layers to define MEMS wafer interconnect layers and electrode layers. Subsequently, one or more insulator layers and a monocrystalline proof mass layer are formed on the membrane wafer over the patterned electrode layers.

At step 63, the proof mass layer(s) on the membrane wafer are selectively etched to form a proof mass array which includes multiple sub-mass structures which are each connected to anchors with one or more compliant spring systems, and which are rigidly connected together. As disclosed herein, the specific configuration of proof mass array and constituent sub-mass structures will depend on the type of transducer design. Generally speaking, the selective etching of the proof mass layer(s) may include forming a patterned transducer resist or mask layer on the proof mass layer(s) to protect selected portions of the monocrystalline proof mass layer, and then selectively etching and removing exposed portions of the proof mass layer(s) with a deep reactive ion etch (DRIE) process to form the proof mass array. The selective etching of the proof mass layer(s) defines the MEMS proof mass, compliant spring systems, and anchor elements which are fixed to the membrane wafer.

At step 64, a release etch process is applied to the membrane wafer to release the MEMS proof mass array and compliant spring systems except for the parts connected to the anchor elements. In selected embodiments, the release etch process may include a vapor release etch (VPE) that is applied to remove a sacrificial dielectric or insulator layer from below the MEMS proof mass array and compliant spring systems, thereby releasing these elements.

At step 65, a cap wafer is fabricated. As will be appreciated, the cap wafer may be fabricated separately from the member wafer and cap wafer, and may include a second crystal silicon wafer substrate which is separately processed with a sequence of processing steps to deposit, pattern and etch insulator layers and conductive layers. For example, the cap wafer may be processed to form an array of through silicon vias (TSVs) using a deep reactive ion etch (DRIE) process to selectively etch the third crystal silicon wafer substrate, followed by a polysilicon deposition process and chemical mechanical polish step to form the TSVs.

At step 66, the membrane wafer is bonded to the cap wafer. In selected embodiments, the cap wafer is bonded with the membrane wafer using AlGe eutectic bonding.

At step 67, additional MEMs wafer processing steps are applied. For example, the cap wafer may be thinned, and contacts to the TSV and redistribution routing layers (RDLs) are fabricated before the final passivation step.

At step 68, the fabrication process ends.

By now, it will be appreciated that there has been provided herein a MEMS inertial sensor device and associated method for operating and fabricating same. The disclosed MEMS inertial sensor device includes a MEMS inertial transducer or sensor, such as a MEMS gyroscope sensor or a MEMS resonant accelerator sensor. The disclosed MEMS inertial sensor device also includes first and second drive actuation units coupled to impart oscillating motion to the MEMS inertial sensor in, respectively, first and second orthogonal directions. In selected embodiments, the first and second drive actuation units include a first drive actuation unit configured to impart oscillating motion to the MEMS inertial sensor in a first direction that is parallel to the surface of the substrate, and a second drive actuation unit configured to impart oscillating motion to the MEMS inertial sensor in a second direction that is orthogonal to the first direction. As disclosed, the MEMS inertial sensor includes a substrate, and also includes a proof mass array positioned in spaced apart relationship above a surface of the substrate. In particular, the proof mass array is constructed with a plurality of proof mass sub-structures which are each separately connected to the substrate with orthogonally disposed pairs of spring suspension structures and which are each rigidly connected to one or more adjacent proof mass sub-structures with one or more connector bars so that the plurality of proof mass sub-structures move as a single proof mass array that can operate at resonant frequencies of at least 100 kHz when oscillating in the first and second orthogonal direction. In selected embodiments, the single proof mass array can operate at different resonant frequencies of at least 100 kHz when oscillating in the first and second orthogonal directions. In other selected embodiments, the proof mass array is an n×m array of proof mass sub-structures connected to form a Lissajous frequency-modulated proof mass. In other embodiments, the plurality of proof mass sub-structures includes a first plurality of proof mass sub-structures and a second plurality of proof mass sub-structures. The first plurality of proof mass sub-structures is connected in a first sub-array of proof mass substructures which are each separately connected to the substrate with orthogonally disposed pairs of spring suspension structures and which are each rigidly connected together with one or more first connector bars. In addition, the second plurality of proof mass sub-structures is connected in a second sub-array of proof mass substructures which are each separately connected to the substrate with orthogonally disposed pairs of spring suspension structures and which are each rigidly connected together with one or more second connector bars. In such embodiments, one or more coupling pivot structures are positioned between the first sub-array of proof mass substructures and the second sub-array of proof mass substructures to impart out-of-phase oscillating motion to the first sub-array of proof mass substructures and the second sub-array of proof mass substructures. In selected embodiments, the orthogonally disposed pairs of spring suspension structures separately connecting each proof mass sub-structure to the substrate may include first and second compliant spring structures connected to first opposed sides of said proof mass sub-structure and disposed to direct oscillating motion at a first resonant frequency to the proof mass sub-structure in alignment with a first direction that is parallel to the surface of the substrate. In addition, the orthogonally disposed pairs of spring suspension structures may include third and fourth compliant spring structures connected to second opposed sides of said proof mass sub-structure and disposed to direct oscillating motion at a second, different resonant frequency to the proof mass sub-structure in alignment with a second direction that is orthogonal to the first direction.

In another form, there has been provided herein a vibratory gyroscope apparatus and associated method for operating and fabricating same. The disclosed vibratory gyroscope apparatus includes a mechanical resonator (e.g., a MEMS gyroscope sensor) having a first mode of vibration in a first axis of motion and an associated first natural frequency, and a second mode of vibration in a second axis of motion having an associated second natural frequency, wherein angular rate of motion of the vibratory gyroscope apparatus couples energy between said first mode of vibration and said second mode of vibration. As disclosed, the mechanical resonator includes a substrate and a proof mass array positioned in spaced apart relationship above a surface of the substrate and constructed with a plurality of proof mass sub-structures which are each separately connected to the substrate with orthogonally disposed pairs of compliant anchor structures and which are each rigidly connected to one or more adjacent proof mass sub-structures with one or more rigid connector bars so that the plurality of proof mass sub-structures move as a single proof mass array that can operate at resonant frequencies of at least 100 kHz when oscillating in the first mode of vibration and/or second mode of vibration. In selected embodiments, the orthogonally disposed pairs of compliant anchor structures include (1) first and second compliant spring structures connected to first opposed sides of said proof mass sub-structure and disposed to direct oscillating motion at a first resonant frequency to the proof mass sub-structure in alignment with a first direction that is parallel to the surface of the substrate, and (2) third and fourth compliant spring structures connected to second opposed sides of said proof mass sub-structure and disposed to direct oscillating motion at a second, different resonant frequency to the proof mass sub-structure in alignment with a second direction that is orthogonal to the first direction. In selected embodiments, the single proof mass array can operate at different resonant frequencies of at least 100 kHz when oscillating in the first and second orthogonal directions. In selected embodiments, the proof mass array is implemented as an n×m array of proof mass sub-structures connected to form a Lissajous frequency-modulated proof mass. In other selected embodiments, the plurality of proof mass sub-structures include a first plurality of proof mass sub-structures connected in a first sub-array of proof mass substructures which are each separately connected to the substrate with orthogonally disposed pairs of compliant anchor structures and which are each rigidly connected together with one or more first rigid connector bars; a second plurality of proof mass sub-structures connected in a second sub-array of proof mass substructures which are each separately connected to the substrate with orthogonally disposed pairs of compliant anchor structures and which are each rigidly connected together with one or more second rigid connector bars; and one or more coupling pivot structures positioned between the first sub-array of proof mass substructures and the second sub-array of proof mass substructures to impart out-of-phase oscillating motion to the first sub-array of proof mass substructures and the second sub-array of proof mass substructures. The disclosed vibratory gyroscope apparatus also includes sensors and actuators for each of the first mode of vibration and the second mode of vibration for, respectively, transduction of a mechanical vibration into an electrical signal and transduction of an electrical signal into a mechanical vibration. In addition, the disclosed vibratory gyroscope apparatus includes drive circuitry connected to the actuators to impart substantially constant, non-zero velocity amplitude vibrations in the first mode of vibration at a first frequency and the second mode of vibration at a second frequency. In selected embodiments, the drive circuitry includes a first drive actuation unit configured to impart oscillating motion to the proof mass array in a first direction that is parallel to the surface of the substrate, and also includes a second drive actuation unit configured to impart oscillating motion to the proof mass array in a second direction that is orthogonal to the first direction. The disclosed vibratory gyroscope apparatus also includes output circuitry connected to the sensors to measure mechanical forces created by the angular rate of motion of the vibratory gyroscope to either or both of the first mode of vibration or second mode of vibration.

In yet another form, there has been provided herein a MEMS gyroscope and associated method for operating and fabricating same. The disclosed MEMS gyroscope includes an N×M proof mass array positioned in spaced apart relationship above a surface of a substrate and constructed with a plurality of proof mass sub-structures arranged in an N×M array, where each proof mass sub-structure is separately connected to the substrate with orthogonally disposed pairs of spring suspension structures and where each proof mass sub-structure is rigidly connected to one or more adjacent proof mass sub-structures with one or more connector bars so that the plurality of proof mass sub-structures can operate at resonant frequencies of at least 100 kHz when oscillating in a first axis direction and a second axis direction. In selected embodiments, the N×M proof mass array may be implemented as an N×M array of proof mass sub-structures connected to form a Lissajous frequency-modulated proof mass. The disclosed MEMS gyroscope also includes (1) a first plurality of N drive actuators configured and connected to impart a first oscillating motion to at least part of the N×M proof mass array in the first axis direction, and (2) a second plurality of M drive actuators configured and connected to impart a second oscillating motion to at least part of the N×M proof mass array in the second axis direction that is orthogonal to the first axis direction, at least one of the first and second axis directions being parallel to the surface of the substrate. In addition, the disclosed MEMS gyroscope includes sensors for transducing oscillating motion of the N×M proof mass array in each of the first and second axis directions into electrical signals. The disclosed MEMS gyroscope also includes output circuitry connected and configured to measure the angular rate of motion of the MEMS gyroscope based on the electrical signals received from the sensors. In selected embodiments, the plurality of proof mass sub-structures arranged in the N×M array are all connected by rigid connector bars to move as a single proof mass array when oscillating in the first axis direction and the second axis direction. In other selected embodiments, the plurality of proof mass sub-structures arranged in the N×M array are connected by rigid connector bars to form N columns of proof mass sub-structures aligned in parallel with the first axis direction, where adjacent columns of proof mass sub-structures from the N columns of proof mass sub-structures are connected by one or more coupling pivot structures to impart out-of-phase oscillating motion to adjacent columns of proof mass sub-structures. In such embodiments, the first plurality of N drive actuators may be is coupled, respectively, to the N columns of proof mass sub-structures to impart out-of-phase oscillating motion in the first axis direction to the adjacent columns of proof mass sub-structures. In addition, the second plurality of M drive actuators may be coupled, respectively, to the N columns of proof mass sub-structures to impart out-of-phase oscillating motion in the second axis direction to the adjacent columns of proof mass sub-structures.

Various illustrative embodiments of the present disclosure have been described in detail with reference to the accompanying figures. While various details are set forth in the foregoing description, it will be appreciated that the present disclosure may be practiced without these specific details, and that numerous implementation-specific decisions may be made to the disclosure described herein to achieve the device designer's specific goals, such as compliance with process technology or design-related constraints, which will vary from one implementation to another. While such a development effort might be complex and time-consuming, it would nevertheless be a routine undertaking for those of ordinary skill in the art having the benefit of this disclosure. For example, selected aspects are depicted with reference to simplified plan views of example MEMS sensor devices without including every device feature or geometry in order to avoid limiting or obscuring the present disclosure. In addition, the methodology of the present disclosure may be applied using materials other than expressly set forth herein. In addition, the process steps may be performed in an alternative order than what is presented. For example, the sequence of wafer bonding steps may be reversed. In addition, it is noted that, throughout this detailed description, certain layers of materials will be deposited and removed to form the depicted MEMS device structures. Where the specific procedures for depositing or removing such layers are not detailed, any desired technique may be used for depositing, removing or otherwise forming such layers at appropriate thicknesses. Such details are well known and not considered necessary to teach one skilled in the art of how to make or use the present disclosure. And while the disclosed MEMS devices may be implemented with accelerometer and/or gyroscope sensors, the fabrication process described herein is not limited to such MEMS sensors or any other type of sensor, but is also applicable to any one of numerous MEMS devices that include some type of proof mass array that is constructed with a plurality of sub-mass structures that are each movably suspended by one or more springs to have very high resonant frequencies. Non-limiting examples of such devices include various types of gyroscopic sensors connected with PLL circuits used with drive and/or sense electrodes.

It is also noted that, throughout this detailed description, certain elements in the figures are illustrated for simplicity and clarity and have not necessarily been drawn to scale so that the illustrated dimensions of some of the elements in the figures may be exaggerated relative to other elements to help improve the understanding of the embodiments of the present invention. Thus, the particular embodiments disclosed above are illustrative only and should not be taken as limitations upon the present invention, as the invention may be modified and practiced in different but equivalent manners apparent to those skilled in the art having the benefit of the teachings herein. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A MEMS inertial sensor device, comprising:
a MEMS inertial sensor; and
first and second drive actuation units coupled to impart oscillating motion to the MEMS inertial sensor in, respectively, first and second orthogonal directions;
wherein the MEMS inertial sensor comprises:
a substrate, and
a proof mass array positioned in spaced apart relationship above a surface of the substrate and constructed with a plurality of proof mass sub-structures which are each separately connected to the substrate with orthogonally disposed pairs of spring suspension structures and which are each rigidly connected to one or more adjacent proof mass sub-structures with one or more connector bars so that the plurality of proof mass sub-structures move as a single proof mass array that can operate at resonant frequencies of at least 100 kHz when oscillating in the first and second orthogonal directions.

2. The MEMS inertial sensor device of claim 1, where the MEMS inertial sensor comprises a MEMS gyroscope sensor or a MEMS resonant accelerator sensor.

3. The MEMS inertial sensor device of claim 1, where the first and second drive actuation units comprise:
a first drive actuation unit configured to impart oscillating motion to the MEMS inertial sensor in a first direction that is parallel to the surface of the substrate; and
a second drive actuation unit configured to impart oscillating motion to the MEMS inertial sensor in a second direction that is orthogonal to the first direction.

4. The MEMS inertial sensor device of claim 1, where the proof mass array comprises an n×m array of proof mass sub-structures connected to form a Lissajous frequency-modulated proof mass.

5. The MEMS inertial sensor device of claim 1, where the plurality of proof mass sub-structures comprise:
a first plurality of proof mass sub-structures connected in a first sub-array of proof mass substructures which are each separately connected to the substrate with orthogonally disposed pairs of spring suspension structures and which are each rigidly connected together with one or more first connector bars;
a second plurality of proof mass sub-structures connected in a second sub-array of proof mass substructures which are each separately connected to the substrate with orthogonally disposed pairs of spring suspension structures and which are each rigidly connected together with one or more second connector bars; and
one or more coupling pivot structures positioned between the first sub-array of proof mass substructures and the second sub-array of proof mass substructures to impart out-of-phase oscillating motion to the first sub-array of proof mass substructures and the second sub-array of proof mass substructures.

6. The MEMS inertial sensor device of claim 1, where the single proof mass array can operate at different resonant frequencies of at least 100 kHz when oscillating in the first and second orthogonal directions.

7. The MEMS inertial sensor device of claim 1, where the orthogonally disposed pairs of spring suspension structures separately connecting each proof mass sub-structure to the substrate comprise:
first and second compliant spring structures connected to first opposed sides of said proof mass sub-structure and disposed to direct oscillating motion at a first resonant frequency to the proof mass sub-structure in alignment with a first direction that is parallel to the surface of the substrate; and
third and fourth compliant spring structures connected to second opposed sides of said proof mass sub-structure and disposed to direct oscillating motion at a second, different resonant frequency to the proof mass sub-structure in alignment with a second direction that is orthogonal to the first direction.

8. A vibratory gyroscope apparatus, comprising:
a mechanical resonator having a first mode of vibration in a first axis of motion and an associated first natural frequency, and a second mode of vibration in a second axis of motion having an associated second natural frequency, wherein angular rate of motion of the vibratory gyroscope apparatus couples energy between said first mode of vibration and said second mode of vibration;
sensors and actuators for each of the first mode of vibration and the second mode of vibration for, respectively, transduction of a mechanical vibration into an electrical signal and transduction of an electrical signal into a mechanical vibration;
drive circuitry connected to the actuators to impart substantially constant, non-zero velocity amplitude vibrations in the first mode of vibration at a first frequency and the second mode of vibration at a second frequency; and
output circuitry connected to the sensors to measure mechanical forces created by the angular rate of motion of the vibratory gyroscope apparatus to either or both of the first mode of vibration or second mode of vibration,
wherein the mechanical resonator comprises a substrate and a proof mass array positioned in spaced apart relationship above a surface of the substrate and constructed with a plurality of proof mass sub-structures which are each separately connected to the substrate with orthogonally disposed pairs of compliant anchor structures and which are each rigidly connected to one or more adjacent proof mass sub-structures with one or more rigid connector bars so that the plurality of proof mass sub-structures move as a single proof mass array that can operate at resonant frequencies of at least 100 kHz when oscillating in the first mode of vibration and/or second mode of vibration.

9. The vibratory gyroscope apparatus of claim 8, where the mechanical resonator comprises a MEMS gyroscope sensor.

10. The vibratory gyroscope apparatus of claim 8, where the drive circuitry comprises:
a first drive actuation unit configured to impart oscillating motion to the proof mass array in a first direction that is parallel to the surface of the substrate; and
a second drive actuation unit configured to impart oscillating motion to the proof mass array in a second direction that is orthogonal to the first direction.

11. The vibratory gyroscope apparatus of claim 8, where the proof mass array comprises an n×m array of proof mass sub-structures connected to form a Lissajous frequency-modulated proof mass.

12. The vibratory gyroscope apparatus of claim 8, where the plurality of proof mass sub-structures comprise:
a first plurality of proof mass sub-structures connected in a first sub-array of proof mass substructures which are each separately connected to the substrate with orthogonally disposed pairs of compliant anchor structures and which are each rigidly connected together with one or more first rigid connector bars;
a second plurality of proof mass sub-structures connected in a second sub-array of proof mass substructures which are each separately connected to the substrate with orthogonally disposed pairs of compliant anchor structures and which are each rigidly connected together with one or more second rigid connector bars; and
one or more coupling pivot structures positioned between the first sub-array of proof mass substructures and the second sub-array of proof mass substructures to impart out-of-phase oscillating motion to the first sub-array of proof mass substructures and the second sub-array of proof mass substructures.

13. The vibratory gyroscope apparatus of claim 8, where the single proof mass array can operate at different resonant frequencies of at least 100 kHz when oscillating in first and second orthogonal directions.

14. The vibratory gyroscope apparatus of claim 8, where the orthogonally disposed pairs of compliant anchor structures separately connecting each proof mass sub-structure to the substrate comprise:
first and second compliant spring structures connected to first opposed sides of said proof mass sub-structure and disposed to direct oscillating motion at a first resonant frequency to the proof mass sub-structure in alignment with a first direction that is parallel to the surface of the substrate; and
third and fourth compliant spring structures connected to second opposed sides of said proof mass sub-structure and disposed to direct oscillating motion at a second, different resonant frequency to the proof mass sub-structure in alignment with a second direction that is orthogonal to the first direction.

15. A MEMS gyroscope comprising:
an N×M proof mass array positioned in spaced apart relationship above a surface of a substrate and constructed with a plurality of proof mass sub-structures arranged in an N×M array, where each proof mass sub-structure is separately connected to the substrate with orthogonally disposed pairs of spring suspension structures and where each proof mass sub-structure is rigidly connected to one or more adjacent proof mass sub-structures with one or more connector bars so that the plurality of proof mass sub-structures can operate at resonant frequencies of at least 100 kHz when oscillating in a first axis direction and a second axis direction;
a first plurality of N drive actuators configured and connected to impart a first oscillating motion to at least part of the N×M proof mass array in the first axis direction;
a second plurality of M drive actuators configured and connected to impart a second oscillating motion to at least part of the N×M proof mass array in the second axis direction that is orthogonal to the first axis direction, at least one of the first and second axis directions being parallel to the surface of the substrate;
sensors for transducing oscillating motion of the N×M proof mass array in each of the first and second axis directions into electrical signals; and
output circuitry connected and configured to measure an angular rate of motion of the MEMS gyroscope based on the electrical signals received from the sensors.

16. The MEMS gyroscope of claim 15, where the plurality of proof mass sub-structures arranged in the N×M array are all connected by rigid connector bars to move as a single proof mass array when oscillating in the first axis direction and the second axis direction.

17. The MEMS gyroscope of claim 15, where the plurality of proof mass sub-structures arranged in the N×M array are connected by rigid connector bars to form N columns of proof mass sub-structures aligned in parallel with the first axis direction, and where adjacent columns of proof mass sub-structures from the N columns of proof mass sub-structures are connected by one or more coupling pivot structures to impart out-of-phase oscillating motion to adjacent columns of proof mass sub-structures.

18. The MEMS gyroscope of claim 17, where the first plurality of N drive actuators is coupled, respectively, to the N columns of proof mass sub-structures to impart out-of-phase oscillating motion in the first axis direction to the adjacent columns of proof mass sub-structures.

19. The MEMS gyroscope of claim 17, where the second plurality of M drive actuators is coupled, respectively, to the N columns of proof mass sub-structures to impart out-of-phase oscillating motion in the second axis direction to the adjacent columns of proof mass sub-structures.

20. The MEMS gyroscope of claim 15, where the N×M proof mass array comprises an N×M array of proof mass sub-structures connected to form a Lissajous frequency-modulated proof mass.
